(19) United States
(12) Patent Application Publication
(10) Pub. No.: US 2010/0188391 A1
(43) Pub. Date: Jul. 29, 2010

(54) ORGANIC LIGHT EMITTING DISPLAY DEVICE AND METHOD OF MANUFACTURING THE SAME

(75) Inventor: Yang-Wan KIM, Yongin-City (KR)

Correspondence Address: STEIN MCEWEN, LLP, 1400 EYE STREET, NW, SUITE 300, WASHINGTON, DC, 20005, US

(73) Assignee: Samsung Mobile Display Co., Ltd., Yongin-City (KR)

(21) Appl. No.: 12/612,036

(22) Filed: Nov. 4, 2009

(30) Foreign Application Priority Data
Jan. 29, 2009 (KR) 10-2009-0006905

(51) Int. Cl. G09G 5/00; H01L 21/28

(52) U.S. Cl. 345/212; 345/211; 438/34; 345/76; 257/E21.158

(57) ABSTRACT

An organic light emitting display device includes a pixel unit that displays an image corresponding to an amount of driving current flowing from a first power supply to a second power supply, wherein the pixel unit includes a pixel that is formed at an intersection portion of a scan line transferring a scan signal and a data line transferring a data signal. The pixel electrode further includes organic light emitting diodes emitting light according to the driving current, and controlling the magnitude of the driving current by controlling a voltage of the data signal corresponding to voltages from the first power supply and the second power supply and a voltage formed on the organic light emitting diode; a first wire transferring the first power to the pixel in a first direction; and a second wire transferring the first power to the pixel in a second direction, wherein the first wire and the second wire are formed to have a thickness thicker in the mid-portion of the pixel unit and is thinner in an outer-portion of the pixel unit, and a method of manufacturing the same.

### CROSS-REFERENCE TO RELATED APPLICATION

This application claims priority to and the benefit of Korean Patent Application No. 10-2009-0006905, filed on Jan. 29, 2009, in the Korean Intellectual Property Office, the entire content of which is incorporated herein by reference.

### BACKGROUND OF THE INVENTION

1. Field of the Invention

An aspect of the present invention relates to an organic light emitting display device and a method of manufacturing the same, and more particularly, to an organic light emitting display device that improves image quality by reducing a difference of voltage drop in power wires, and a method of manufacturing the same.

2. Description of the Related Art

Recently, various flat panel display devices having reduced weight and volume as compared to cathode ray tubes have been developed. Amongst the various types of flat panel display devices, there are liquid crystal display (LCD) devices, field emission display (FED) devices, plasma display panels (PDP), organic light emitting display (OLED) devices, etc.

Amongst other advantages, the organic light emitting display devices have excellent color reproducibility, and are very slim, making them commonly used in personal digital assistants (PDAs) and MP3 players as well as cellular phones.

The organic light emitting display device displays an image using organic light emitting diodes (OLED) that determine brightness according to an amount of input current.

The organic light emitting diodes include red, green or blue light emitting layers positioned between an anode electrode and a cathode electrode, and determine brightness depending on the amount of current flowing between the anode electrode to the cathode electrode.

The organic light emitting diodes described above emit light corresponding to the flow of current, wherein the current flows according to the power applied between the anode electrode and the cathode electrode.

First power is transferred to the anode electrode through a line and second power is transferred to the cathode electrode through a front surface. Therefore, due to the line and internal resistance of material in the cathode electrode, a voltage difference occurs between the voltage of the first and second power transferred to the organic light emitting diodes in the outer surface of the display device and the voltage of the first power and the second power transferred to the organic light emitting diodes inside the display device. In other words, the absolute value of the voltage of the first power and the second power transferred to the organic light emitting diodes in the outer surface of the display device has a greater value than that of the first power and second power transferred to the organic light emitting diodes inside the display device. Therefore, a problem arises in that brightness difference occurs between the inner and the outer surfaces of the display device.

Also, the respective organic light emitting diodes deteriorate over time, which causes unnecessary current to flow into the organic light emitting diodes, thereby forming after-images, etc.

### SUMMARY OF THE INVENTION

Therefore, it is an object of the present invention to provide an organic light emitting display device that prevents non-uniformity in brightness and after-images, and a method of manufacturing the same.

In order to accomplish the above object, according to a first aspect of the present invention, there is provided an organic light emitting display device including: a pixel unit that displays an image corresponding to an amount of driving current flowing from a first power supply to a second power supply corresponding to a data signal, wherein the pixel unit includes: a pixel that is formed at an intersection portion of a scan line transferring a scan signal and a data line transferring the data signal, the pixel includes organic light emitting diodes that emit light according to the driving current, and controls the magnitude of the driving current by controlling a voltage of the data signal corresponding to voltages from the first power supply and the second power supply and a voltage formed on the organic light emitting diode; a first wire transferring the first power to the pixel in a first direction; and a second wire transferring the first power to the pixel in a second direction, wherein the first wire and the second wire are formed to be thicker in the middle portion of the pixel unit than at the outer portion of the pixel unit.

According to a second aspect of the present invention, there is provided a method of manufacturing an organic light emitting display device including forming a pixel on a substrate, the forming the pixel including: forming a semiconductor layer and a first electrode of a capacitor on the substrate; forming an insulating film on the semiconductor layer and the first electrode of the capacitor and forming a gate metal and a second electrode of the capacitor, the second electrode of the capacitor being electrically coupled to a second electrode of a capacitor of an adjacent pixel; and forming a contact hole on the insulating film and forming source drain metals on the contact hole, the source drain metals being electrically coupled to the semiconductor layer, and the source drain metals and the second electrode of the capacitor being wider in the middle portion of the substrate than in the outer portion of the substrate.

According to another aspect of the present invention, the pixel formed on the substrate may be a pixel that is formed at an intersection portion of a scan line transferring a scan signal and a data line transferring the data signal, the pixel including organic light emitting diodes emitting light by the driving current and controlling the magnitude of the driving current by controlling the voltage of the data signal corresponding to the voltages from the first power supply and the second power supply and the voltage formed on the organic light emitting diode.

According to another aspect of the present invention, the lines to which the first power is transferred are formed in a mesh type and the width of the lines is controlled, making it possible to reduce the drop in the voltage from the first power supply, and also the difference between the magnitude of the drop in the voltage from the first power supply and the magnitude of the drop in the voltage from the second power supply is reduced, making it possible to achieve uniform brightness.

According to another aspect of the present invention, the deterioration of the organic light emitting diode is compensated, making it possible to reduce after-images.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a view of an organic light emitting display device according to an aspect of the present invention;

FIG. 2 illustrates a change in thickness of a first line of an organic light emitting display device according to an aspect of the present invention;

FIG. 3 is a circuit diagram showing a pixel of the organic light emitting display device of FIG. 1;

FIG. 4 is a waveform view showing a signal input to the pixel of FIG. 3; and

FIG. 5 is a cross-sectional view of a pixel of a pixel unit of an organic light emitting display device according to an aspect of the present invention.

### DETAILED DESCRIPTION OF THE EMBODIMENTS

Reference will now be made in detail to the present embodiments of the present invention, examples of which are illustrated in the accompanying drawings. The embodiments are described below in order to explain the present invention by referring to the figures.

Here, when a first element is described as being coupled to a second element, the first element may be not be only directly coupled to the second element but may also be indirectly coupled to the second element via a third element. Moreover, it is to be understood that where is stated herein that one film or layer is “formed on” or “disposed on” a second layer or film, the first layer or film may be formed or disposed directly on the second layer or film or there may be intervening layers or films between the first layer or film and the second layer or film. Further, as used herein, the term “formed on” is used with the same meaning as “located on” or “disposed on” and is not meant to be limiting regarding any particular fabrication process. Further, some of the elements that are not essential to the complete understanding of the invention are omitted for clarity. Also, like reference numerals refer to like elements throughout. Hereinafter, exemplary embodiments of the present invention will be described with reference to the accompanying drawings.

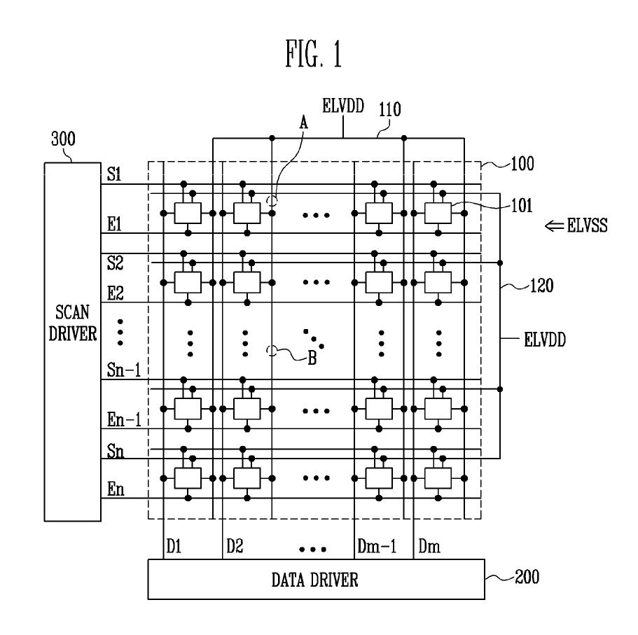

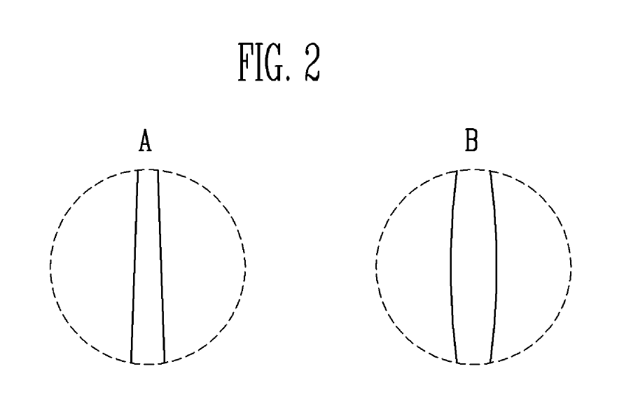

FIG. 1 is a view of an organic light emitting display device according to an aspect of the present invention, and FIG. 2 illustrates a change in thickness of a first line of an organic light emitting display device according to an aspect of the present invention. For convenience of explanation, although the change in thickness of the first line is shown in FIG. 2, such a change in thickness of a line may also be applied to a second line.

Referring to FIGS. 1 and 2, the organic light emitting display device includes a pixel unit 100, a data driver 200, and a scan driver 300.

The pixel unit 100 is arranged with a plurality of pixels 101, wherein each pixel 101 includes an organic light emitting diode (not shown) emitting light corresponding to current flow. On the pixel unit 100, n scan lines S1, S2, . . . Sn-1, and Sn are formed in a row direction and transfer scan signals, n light emitting control lines E1, E2, En-1, and En are formed in a row direction and transfer light emitting control signals, and m data lines D1, D2, . . . Dm-1, and Dm are formed in a column direction and transfer data signals.

Also, the pixel unit 100 is driven by receiving first power ELVDD and second power ELVSS. Therefore, the pixel unit 100 emits light by allowing current to flow on the organic light emitting diode according to the scan signals, light emitting control signals, data signals, first power ELVDD and second power ELVSS, thereby displaying an image.

At this time, in order to reduce the drop in the voltage from the first power supply ELVDD, the first power ELVDD is transferred in a horizontal direction and a vertical direction of the pixel unit 100. In other words, a plurality of first lines 110 are formed in a vertical direction of the pixel unit 100 and a plurality of second lines 120 are formed in a horizontal direction thereof, wherein the points where the first lines 110 and the second lines 120 intersect contact each other. Therefore, the first power ELVDD is transferred to the pixel unit 100 in a horizontal direction and in a vertical direction by the first lines 110 and the second lines 120, respectively, and in particular, at the points where the first lines 110 and the second lines 120 intersect each other the first power ELVDD is transferred through the first line 110 and the second line 120, thereby reducing the drop in the voltage from the first power supply ELVDD.

As shown in FIG. 2, the first line 110 and the second line 120 are thicker at the inner surface of the pixel unit 100 than at the outer surface of the pixel unit 100. In other words, due to the differences in thicknesses of the first line 110 and the second line 120, the drop in the first power ELVDD voltage transferred to the pixel positioned in the inner surface of the pixel unit 100 becomes smaller than the drop in the first power ELVDD voltage transferred to the pixel positioned in the outer surface of the pixel unit 100. Therefore, the difference between the drop in the voltage from the first power supply ELVDD and the drop in the voltage from the second power supply ELVSS can be reduced.

The data driver 200, which is a device that generates data signals, generates data signals using image signals R, G, B data having red, blue and green components. The data driver 200 applies the data signals generated by coupling an output channel outputting the data signals to the data lines D1, D2, . . . Dm-1, and Dm of the pixel unit 100 to the pixel unit 100.

The scan driver 300, which is a device that generates scan signals, is coupled to scan lines S1, S2, . . . Sn-1, and Sn and light emitting control lines E1, E2, En-1, and En to transfer scan signals and light emitting control signals to a specific row of the pixel 100. The data signals output from the data driver 200 are transferred to the pixel 101 and in conjunction with the scan signals the voltage corresponding to the data signals is transferred to the pixel 101, thereby generating driving current from the pixel. The driving current generated from the pixel 101 transferred with the light emitting control signals flow to the organic light emitting diode.

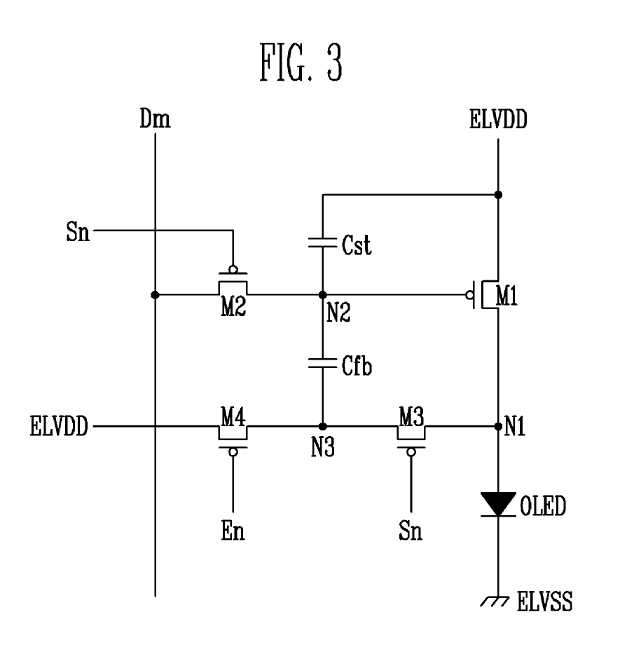

FIG. 3 is a circuit diagram showing a pixel of the organic light emitting display device of FIG. 1. Referring to FIG. 3, a pixel 101 includes a first transistor M1, a second transistor M2, a third transistor M3, a fourth transistor M4, a first capacitor Cst, a second capacitor Cfb, and an organic light emitting diode OLED.

A source of the first transistor M1 is coupled to a first power supply ELVDD, a drain thereof is coupled to a first node N1, and a gate is coupled to a second node N2.

A source of the second transistor M2 is coupled to a data line Dm, a drain thereof is coupled to the second node N2, and a gate thereof is coupled to a scan line Sn.

A source of the third transistor M3 is coupled to the first node N1, a drain is coupled to a third node N3, and a gate is coupled to the scan line Sn.

A source of the fourth transistor M4 is coupled to the first power supply ELVDD, a drain is coupled to the third node N3, and a gate is coupled to a light emitting control line En.

A first electrode of the first capacitor Cst is coupled to the first power supply ELVDD and a second electrode thereof is coupled to the second node N2.

A first electrode of the second capacitor Cfb is coupled to the second node N2 and a second electrode thereof is coupled to the third node N3.

An anode electrode of the organic light emitting diode OLED is coupled to the first node N1 and a cathode electrode thereof is coupled to a second power supply ELVSS.

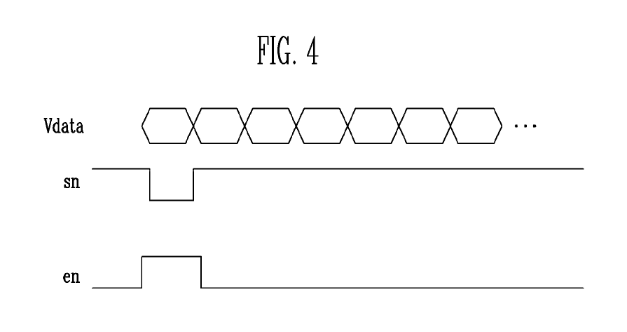

FIG. 4 is a waveform view showing a signal input to the pixel of FIG. 3. Referring to FIG. 4, the pixel 101 receives a scan signal sn through the scan line Sn, a data signal Vdata through the data line Dm, and a light emitting control signal en through the light emitting control line En.

First, if the scan signal becomes a low state and the light emitting control signal en becomes a high state, the second transistor M2 and the third transistor M3 become a turn-on state and the fourth transistor M4 becomes a turn-off state. If the second transistor M2 becomes the turn-on state, the data signal is transferred to the second node N2 and the voltage from the organic light emitting diode OLED is transferred to the third node N3. Therefore, the voltage corresponding to the difference between the voltage from the first power supply ELVDD and the voltage of the data signal Vdata is stored in the first capacitor Cst, and the voltage corresponding to the difference between the voltage of the data signal Vdata and the voltage from the organic light emitting diode OLED is stored in the second capacitor Cfb.

If the scan signal becomes a high state and the light emitting control signal becomes a low state, the second transistor M2 and the third transistor M3 become a turn-off state and the fourth transistor M4 becomes a turn-on state. Therefore, the first power ELVDD is transferred to the third node N3 so that the voltage from the third node N3 is changed from the voltage from the organic light emitting diode OLED to the voltage from the first power supply ELVDD. In other words, the voltage from the third node n3 rises due to the difference between the voltage from the organic light emitting diode OLED and the voltage from the first power supply ELVDD.

In other words, the voltage from the second node N2 corresponds to the following equation 1.

$${V}_{N 2} = {V}_{G} = {V}_{data} + \frac{{C}_{fb}}{{C}_{st} + {C}_{fb}} ( \begin{matrix}ELVDD - \\ ( ELVSS + {V}_{EL} )\end{matrix} ) \qquad [ Equation 1 ]$$

Here, V_{N2} represents the voltage from the second node N2, V_{G} represents the voltage from the gate of the first transistor M1, Vdata represents the voltage of the data signal, Cst represents the electrostatic capacity of the first capacitor, Cfb represents the electrostatic capacity of the second capacitor, ELVSS represents the voltage from the second power supply, and the V_{EL} represents the threshold voltage from the organic light emitting diode OLED.

Therefore, the current flowing from the source of the first transistor M1 to the drain thereof corresponds to the following equation 2.

I_{OLED}=k(V_{GS}−Vₜₕ)² [Equation 2]

I_{OLED} represents the current flowing on the organic light emitting diode, V_{GS} represents the difference between the voltage from the source of the first transistor M1 and the voltage from the gate thereof, Vth represents the threshold voltage from the first transistor M1.

More specifically, the current flowing onto the organic light emitting diode OLED corresponds to the following equation 3.

$${I}_{OLED} - {k ( ELVLDD - ( {V}_{data} + \frac{{C}_{fb}}{{C}_{st} + {C}_{fb}} ( \begin{matrix}ELVDD - \\ ( ELVSS + {V}_{EL} )\end{matrix} ) ) - Vth )}^{2} \qquad [ Equation 3 ]$$

Referring to equation 3, the current flowing on the organic light emitting diode OLED is affected by the first power ELVDD, the second power ELVSS, and the threshold voltage of the organic light emitting diode OLED, etc.

More specifically, the threshold voltage from the organic light emitting diode OLED is changed according to the life span of the organic light emitting diode OLED, creating a problem since the current flowing on the organic light emitting diode (OLED) is changed as time elapses. This problem causes after-images. However, if the voltages charged in the first capacitor Cst and the second capacitor Cfb are controlled depending on the change in the voltage corresponding to the threshold voltage V_{EL} of the organic light emitting diode OLED as shown in FIG. 3, the current flowing on the organic light emitting diode OLED can constantly flow regardless of the life span of the organic light emitting diode OLED. Therefore, the generation of the after-images is suppressed.

Also, referring to FIG. 3, the current flowing on the organic light emitting diode OLED flows according to the voltages from the first power supply ELVDD and the second power supply ELVSS. Therefore, the first power ELVDD is transferred to a wire having a line shape, and the second power ELVSS is transferred to the cathode electrode which is formed on an outermost surface of the pixel unit.

Although the wire and the cathode electrode described above are conductors, the magnitude thereof is changed depending on the positions of the wire and the cathode in the pixel unit, due to internal resistance. More specifically, a greater voltage drop is generated in the first power supply ELVDD and the second power ELVSS transferring power to the pixel formed on the central or inner portion of the pixel unit 100 than in the first power supply ELVDD and the second power ELVSS transferring power to the pixel formed on the outer surface or portion of the pixel unit 100. Therefore, due to the drop in the voltage from the first power supply ELVDD and from the second power ELVSS, the amount of charge on the first and second capacitors Cst and Cfb is changed. In other words, the amount of current flowing onto the organic light emitting diode OLED is changed and thus the brightness of the pixel is changed. Thereby, a pixel located in the central or inner portion of the pixel unit 100 is not as bright as a pixel that is located in the outer portion of the pixel unit 100, causing the pixel unit 100 to have a non-uniform brightness.

The cathode electrode transferring the second power ELVSS to the OLED is formed on the front surface of the pixel unit 100, whereas the wire transferring the first power ELVDD to the OLED is formed on the pixel unit 100 in a line shape, such that the change in the voltage from the first power supply ELVDD to the OLED is greater than the change in the voltage from the second power supply ELVSS to the OLED.

If the change in the voltage from the first power supply ELVDD and the change in the voltage from the second power supply ELVSS have the same magnitude (generally the voltage from the first power supply is positive voltage and the voltage from the second power supply is negative voltage so that if the change in the voltage is generated in the same magnitude, the voltage from the first power supply is changed from 5V to 4.5V and the voltage from the second power supply is changed from −5V to −4.5V by way of example), there is little change in the amount of charge located in the first and second capacitors Cst and Cfb. Therefore, the current flowing on the organic light emitting diode OLED becomes non-uniform by the drop in the voltage from the first power supply ELVDD. However, if the change in the voltage from the first power supply ELVDD and the change in the voltage from the second power supply ELVSS have different magnitudes, there is a change in the amount of charge located in the first and second capacitors Cst and Cfb, such that a change is generated in the voltage from the second node N2. Therefore, there is a concern that the brightness non-uniformity may be generated in the pixel for reducing the after-images.

Therefore, it is very important to reduce the difference between the voltage drop from the first power supply ELVDD and the voltage drop from the second power supply ELVSS.

Accordingly, in order to reduce the drop in the voltage from the first power supply ELVDD and the drop in the voltage from the second power supply ELVSS, the power line to which the first power ELVDD is transferred is formed in a mesh type, and a width of a first wire positioned in a vertical direction of the power line, to which the first power ELVDD is transferred and a width of a second wire positioned in a horizontal direction of the power line, are formed to be the thicker in the middle portion of the pixel unit 100 than in the outer portion of the pixel unit 100.

Therefore, the first power ELVDD is uniformly transferred by the first and second wires formed in a mesh type and the difference between the drop in the voltage from the first power supply ELVDD and the drop in the voltage from the second power supply ELVSS is reduced by the different widths of the first wire and the second wire according to their positions in the pixel unit 100.

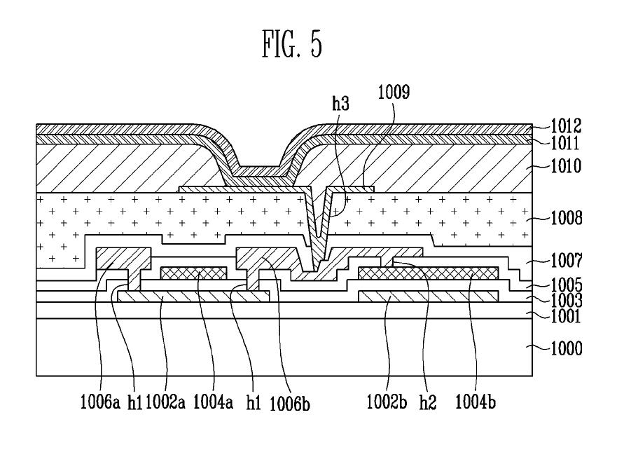

FIG. 5 is a cross-sectional view of a pixel located in a pixel unit of the organic light emitting display device according to an aspect of the present invention. Referring to FIG. 5, a buffer layer 1001 is formed on a substrate 1000, and semiconductor layers 1002a and 1002b are deposited on the buffer layer 1001 and then are patterned. The semiconductor layers 1002a and 1002b become a channel region 1002a of a first transistor M1 and a first electrode 1002b of a first capacitor Cst. An insulating film 1003 is formed thereon and then a metal layer is deposited and patterned, thereby forming a gate metal 1004a and a second electrode 1004b of the first capacitor Cst. Although not shown, the second electrode 1004b of the first capacitor Cst is coupled to the second electrode of the first capacitor Cst that is located in the adjacent pixel that receives the same scan signal. The gate metal 1004a and the second electrode 1004b of the first capacitor Cst use metal such as MoW. An insulating layer 1005 is formed thereon and then a metal layer is formed on the insulating layer 1005 and then is patterned, thereby forming source drain metals 1006a and 1006b. The source drain metals 1006a and 1006b use metal such as silver alloy and chrome, etc. A contact hole h1 is formed on the insulating layer 1005 so that the source drain metals 1006a and 1006b contact the semiconductor layer 1002a through the contact hole h1. Also, the source drain metals 1006a and 1006b contact the second electrode 1004b of the first capacitor Cst through the contact hole h2.

Another insulating film 1007 and a planarization film 1008 are deposited sequentially on the drain metals 1006a and 1006b and the insulating layer 10005 and then a contact hole h3 is formed on the insulating film 1007. An anode electrode 1009 is formed to allow the anode electrode to contact the source drain metal 1006b. A pixel define film 1010, an organic light emitting layer 1011 and a cathode electrode 1012 are formed thereon. The cathode electrode 1012 is formed on the front surface of the pixel unit 100.

As described above, if the second electrode 1004b of the first capacitor Cst is coupled to the second electrode of the first capacitor of the adjacent pixel and the source drain metal 1006b is coupled to the second electrode 1004b of the first capacitor Cst, the wire transferring the first power ELVDD is formed in a mesh type. In other words, the first wire in a vertical direction is formed of the source drain metal and the second wire in the horizontal direction is formed of the second electrodes 1004b of the first capacitor Cst. The resistance of the first wire and the resistance of the second wire become the same.

While aspects of the present invention have been described in connection with certain exemplary embodiments, it is to be understood that the invention is not limited to the disclosed embodiment, but, on the contrary, is intended to cover various modifications and equivalent arrangements included within the spirit and scope of the appended claims, and equivalents thereof.

What is claimed is:

1. An organic light emitting display device, comprising:
a pixel unit that displays an image corresponding to an amount of driving current flowing from a first power supply to a second power supply according to a data signal, the pixel unit comprising a plurality of pixels having light emitting diodes emitting light according to the driving current, wherein each pixel is formed at intersection portions of a scan line transferring a scan signal and a data line transferring the data signal, and the pixel unit further controls a magnitude of the driving current by controlling a voltage of the data signal corresponding to voltages from the first power supply and the second power supply and a voltage formed on the organic light emitting diode;
a first wire transferring the first power to the pixel in a first direction; and
a second wire transferring the first power to the pixel in a second direction,
wherein the first wire and the second wire are formed to be thicker in a middle portion of the pixel unit than at an outer portion of the pixel unit.

2. The organic light emitting display device as claimed in claim 1, wherein the first wire and the second wire have a same internal resistance.

3. The organic light emitting display device as claimed in claim 1, wherein the first wire is an alloy comprising aluminum.

4. The organic light emitting display device as claimed in claim 1, wherein the second wire is an alloy comprising molybdenum.

5. The organic light emitting display device as claimed in claim 1, wherein the pixel further comprises:
a first transistor having a source that is coupled to the first power supply, a drain that is coupled to a first node, and a gate that is coupled to a second node;
a second transistor having a source that is coupled to the data line, a drain that is coupled to the second node, and a gate that is coupled to the scan line;
a third transistor having a source that is coupled to the first node, a drain that is coupled to a third node, and a gate that is coupled to the scan line;
a fourth transistor having a source that is coupled to the first power supply, a drain that is coupled to the third node, and a gate that is coupled to a light emitting control line;
a first capacitor having a first electrode that is coupled to the first power supply and a second electrode that is coupled to the second node;
a second capacitor having a first electrode that is coupled to the second node and a second electrode that is coupled to the third node; and
an organic light emitting diode having an anode electrode that is coupled to the first node and a cathode electrode that is coupled to the second power supply.

6. A method of manufacturing an organic light emitting display device, the method comprising:
forming a pixel on a substrate,
forming a semiconductor layer and a first electrode of a capacitor on the substrate;
forming an insulating film on the semiconductor layer and the first electrode of the capacitor and forming a gate metal and a second electrode of the capacitor, the second electrode of the capacitor being electrically coupled to a second electrode of a capacitor of an adjacent pixel; and
forming a contact hole on the insulating film and forming source drain metals on the contact hole, the source drain metals being electrically coupled to the semiconductor layer, and the source drain metals and the second electrode of the capacitor being wider in a middle portion of the substrate than in the outer portion of the substrate.

7. The method of manufacturing the organic light emitting display device as claimed in claim 6, wherein the pixel comprises organic light emitting diodes emitting light according to the driving current, and the pixel is formed at an intersection portion of a scan line transferring a scan signal and a data line transferring the data signal, and the pixel controls a magnitude of the driving current by controlling a voltage of the data signal corresponding to voltages from the first power supply and the second power supply and a voltage formed on the organic light emitting diode.

8. An organic light emitting display device, comprising:
a pixel unit including a plurality of pixels that displays an image according to an amount of driving current flowing from a first power supply to a second power supply;
a scan driver providing a scan signal to each of the plurality of pixels in the pixel unit through a scan line; and
a data driver providing a data signal to each of the plurality of pixels in the pixel unit through a data line;
wherein the pixels are formed at intersections of the scan lines and the data lines and are connected to the first power supply through the first and second wires, wherein the first and second wires providing power to the pixels located in a middle portion of the pixel unit are formed to be thicker than the first and second wires providing power to the pixels located at an outer portion of the pixel unit.

9. The organic light emitting display device as claimed in claim 8, wherein the first wires transferring the first power to the pixels are formed in a first direction and the second wires transferring the first power to the pixels are formed in a second direction perpendicular to the first direction.

10. The organic light emitting display device as claimed in claim 8, wherein the first and second wires have a same internal resistance.

11. The organic light emitting display device as claimed in claim 8, wherein the first wires are an alloy comprising aluminum.

12. The organic light emitting display device as claimed in claim 8, wherein the second wires are an alloy comprising molybdenum.

13. The organic light emitting display device as claimed in claim 8, wherein each of the pixels further comprises:
a first transistor having a source that is coupled to the first power supply, a drain that is coupled to a first node, and a gate that is coupled to a second node;
a second transistor having a source that is coupled to the data line, a drain that is coupled to the second node, and a gate that is coupled to the scan line;
a third transistor having a source that is coupled to the first node, a drain that is coupled to a third node, and a gate that is coupled to the scan line;
a fourth transistor having a source that is coupled to the first power supply, a drain that is coupled to the third node, and a gate that is coupled to a light emitting control line;
a first capacitor having a first electrode that is coupled to the first power supply and a second electrode that is coupled to the second node;
a second capacitor having a first electrode that is coupled to the second node and a second electrode that is coupled to the third node; and
an organic light emitting diode having an anode electrode that is coupled to the first node and a cathode electrode that is coupled to the second power supply.
